(19) United States
(12) Patent Application Publication
(10) Pub. No.: US 2025/0220098 A1
(43) Pub. Date: Jul. 3, 2025

(54) ELECTRONIC DEVICE COMPRISING HOUSING

(71) Applicant: Samsung Electronics Co., Ltd., Suwon-si (KR)

(72) Inventors: Kidoc SON, Suwon-si (KR); Kyunghwan SONG, Suwon-si (KR); Hyunsuk CHOI, Suwon-si (KR); Youngchun KIM, Suwon-si (KR); Taejeong KIM, Suwon-si (KR); Byounggyu PARK, Suwon-si (KR); Hyuckki LEE, Suwon-si (KR)

(21) Appl. No.: 19/080,207

(22) Filed: Mar. 14, 2025

Related U.S. Application Data
(63) Continuation of application No. PCT/KR2023/014100, filed on Sep. 18, 2023.

(30) Foreign Application Priority Data
Sep. 16, 2022 (KR) 10-2022-0117178
Oct. 13, 2022 (KR) 10-2022-0131551
Sep. 18, 2023 (KR) 10-2023-0124319

(51) Int. Cl. H04M 1/02; C23C 4/18; C23C 14/34; C23C 14/58; C23C 28/00

(52) U.S. Cl. CPC H04M 1/0283; C23C 4/18; C23C 14/34; C23C 14/5813; C23C 28/345; H04M 1/0262

(57) ABSTRACT

In an electronic device comprising a housing, according to various embodiments of the present disclosure, the housing may comprise: an aluminum substrate; a thermal spray coating layer formed on the aluminum substrate and including a first region having a first thickness and a second region having a second thickness thinner than the first thickness; an oxide film layer formed on the thermal spray coating layer or the aluminum substrate; and a deposited film layer formed on at least a portion of the thermal spray coating layer.

### CROSS-REFERENCE TO RELATED APPLICATIONS

This application is a continuation of International Application No. PCT/KR2023/014100 designating the United States, filed on Sep. 18, 2023, in the Korean Intellectual Property Receiving Office and claiming priority to Korean Patent Application Nos. 10-2022-0117178, filed on Sep. 16, 2022, 10-2022-0131551, filed on Oct. 13, 2022 and 10-2023-0124319, filed on Sep. 18, 2023, in the Korean Intellectual Property Office, the disclosures of each of which are incorporated by reference herein in their entireties.

### BACKGROUND

### Field

The disclosure relates to an electronic device including a housing.

### Description of Related Art

Due to the remarkable development of information communication technology and semiconductor technology, the distribution and use of various electronic devices are rapidly increasing. In particular, recent electronic devices are being developed to be portable and capable of communication.

In addition, the electronic devices may output information stored therein as sound or an image. As the degree of integration of electronic devices increases and ultra-high-speed and high-capacity wireless communication become more widespread, a single electronic device, such as a mobile communication terminal, may be now equipped with various functions. For example, in addition to communication functions, entertainment functions such as gaming, multimedia functions such as music/video playback, and communication and security functions for mobile banking, as well as schedule management and electronic wallet functions, are being integrated into a single electronic device. These electronic devices are being miniaturized to be conveniently carried by users.

With the recent emphasis on miniaturization, slimness, and portability of portable electronic devices such as smartphones, research is continuously being conducted to aesthetically enhance the design of the appearance of electronic devices.

### SUMMARY

According to an example embodiment of the disclosure, in an electronic device including a housing, the housing includes: an aluminum substrate, a thermal spray coating layer formed on the aluminum substrate, and including a first area having a first thickness, and a second area having a second thickness less than the first thickness, an oxide film layer formed on the thermal spray coating layer or the aluminum substrate, and a deposition film layer formed on at least a portion of the thermal spray coating layer.

According to an example embodiment of the disclosure, a method of manufacturing a housing for an electronic device may include: forming a thermal spray coating layer on an aluminum substrate through thermal spray coating, polishing the thermal spray coating layer, machining at least a portion of the thermal spray coating layer with a laser such that the thermal spray coating layer includes a first area having a first thickness and a second area having a second thickness less than the first thickness, forming an oxide film layer through an anodizing process, forming a deposition film layer through a deposition process, and machining at least a portion of the deposition film layer with a laser.

### BRIEF DESCRIPTION OF THE DRAWINGS

The above and other aspects, features and advantages of certain embodiments of the present disclosure will be more apparent from the following detailed description, taken in conjunction with the accompanying drawings, in which:

FIG. 1 is a block diagram illustrating an example electronic device in a network environment according to various embodiments;

FIG. 2 is a front perspective view illustrating an example electronic device according to various embodiments;

FIG. 3 is a rear perspective view illustrating the electronic device according to various embodiments;

FIG. 4 is an exploded perspective view of an example electronic device according to various embodiments;

FIG. 5 is a cross-sectional view illustrating a cross-section of a housing according to various embodiments;

FIG. 6 is a flowchart illustrating an example method of manufacturing a housing according to various embodiments;

FIG. 7 is a cross-sectional view illustrating an example first process of the example method of manufacturing the housing according to various embodiments;

FIG. 8 is a cross-sectional view illustrating an example second process of the method of manufacturing the housing according to various embodiments;

FIG. 9 is a cross-sectional view illustrating an example third process of the example method of manufacturing the housing according to various embodiments;

FIG. 10A is a diagram illustrating brightness differences according to thickness differences in the thermal spray coating layers according to various embodiments;

FIG. 10B is a diagram illustrating gloss differences according to laser machining thickness differences according to various embodiments;

FIG. 11 is a cross-sectional view illustrating an example fourth process of the example method of manufacturing the housing according to various embodiments;

FIG. 12 is a cross-sectional view illustrating an example fifth process of the example method of manufacturing the housing according to various embodiments;

FIG. 13 is a cross-sectional view illustrating an example housing according to various embodiments.

### DETAILED DESCRIPTION

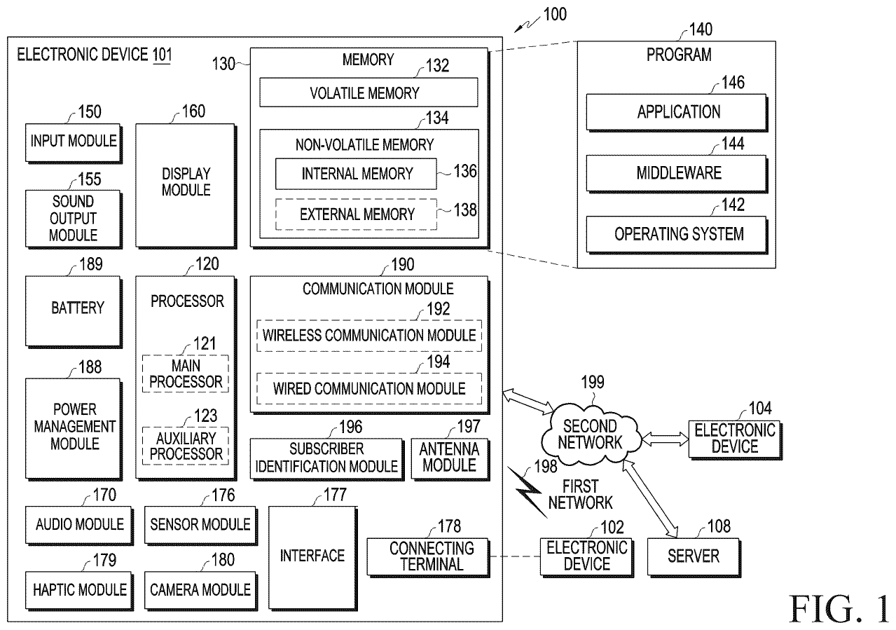

FIG. 1 is a block diagram illustrating an example electronic device 101 in a network environment 100 according to various embodiments.

Referring to FIG. 1, the electronic device 101 in the network environment 100 may communicate with an electronic device 102 via a first network 198 (e.g., a short-range wireless communication network), or at least one of an electronic device 104 or a server 108 via a second network 199 (e.g., a long-range wireless communication network). According to an embodiment, the electronic device 101 may communicate with the electronic device 104 via the server 108. According to an embodiment, the electronic device 101 may include a processor 120, memory 130, an input module 150, a sound output module 155, a display module 160, an audio module 170, a sensor module 176, an interface 177, a connecting terminal 178, a haptic module 179, a camera module 180, a power management module 188, a battery 189, a communication module 190, a subscriber identification module (SIM) 196, or an antenna module 197. In various embodiments, at least one of the components (e.g., the connecting terminal 178) may be omitted from the electronic device 101, or one or more other components may be added in the electronic device 101. In various embodiments, some of the components (e.g., the sensor module 176, the camera module 180, or the antenna module 197) may be implemented as a single component (e.g., the display module 160).

The processor 120 may include various processing circuitry and/or multiple processors. For example, as used herein, including the claims, the term “processor” may include various processing circuitry, including at least one processor, wherein one or more of at least one processor, individually and/or collectively in a distributed manner, may be configured to perform various functions described herein. As used herein, when “a processor”, “at least one processor”, and “one or more processors” are described as being configured to perform numerous functions, these terms cover situations, for example and without limitation, in which one processor performs some of recited functions and another processor(s) performs other of recited functions, and also situations in which a single processor may perform all recited functions. Additionally, the at least one processor may include a combination of processors performing various of the recited/disclosed functions, e.g., in a distributed manner. At least one processor may execute program instructions to achieve or perform various functions. The processor 120 may execute, for example, software (e.g., a program 140) to control at least one other component (e.g., a hardware or software component) of the electronic device 101 coupled with the processor 120, and may perform various data processing or computation. According to an embodiment, as at least part of the data processing or computation, the processor 120 may store a command or data received from another component (e.g., the sensor module 176 or the communication module 190) in volatile memory 132, process the command or the data stored in the volatile memory 132, and store resulting data in non-volatile memory 134. According to an embodiment, the processor 120 may include a main processor 121 (e.g., a central processing unit (CPU) or an application processor (AP)), or an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. For example, when the electronic device 101 includes the main processor 121 and the auxiliary processor 123, the auxiliary processor 123 may be adapted to consume less power than the main processor 121, or to be specific to a specified function. The auxiliary processor 123 may be implemented as separate from, or as part of the main processor 121.

The auxiliary processor 123 may control at least some of functions or states related to at least one component (e.g., the display module 160, the sensor module 176, or the communication module 190) among the components of the electronic device 101, instead of the main processor 121 while the main processor 121 is in an inactive (e.g., sleep) state, or together with the main processor 121 while the main processor 121 is in an active state (e.g., executing an application). According to an embodiment, the auxiliary processor 123 (e.g., an image signal processor or a communication processor) may be implemented as part of another component (e.g., the camera module 180 or the communication module 190) functionally related to the auxiliary processor 123. According to an embodiment, the auxiliary processor 123 (e.g., the neural processing unit) may include a hardware structure specified for artificial intelligence model processing. An artificial intelligence model may be generated by machine learning. Such learning may be performed, e.g., by the electronic device 101 where the artificial intelligence is performed or via a separate server (e.g., the server 108). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted Boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 130 may store various data used by at least one component (e.g., the processor 120 or the sensor module 176) of the electronic device 101. The various data may include, for example, software (e.g., the program 140) and input data or output data for a command related thereto. The memory 130 may include the volatile memory 132 or the non-volatile memory 134.

The program 140 may be stored in the memory 130 as software, and may include, for example, an operating system (OS) 142, middleware 144, or an application 146.

The input module 150 may receive a command or data to be used by another component (e.g., the processor 120) of the electronic device 101, from the outside (e.g., a user) of the electronic device 101. The input module 150 may include, for example, a microphone, a mouse, a keyboard, a key (e.g., a button), or a digital pen (e.g., a stylus pen).

The sound output module 155 may output sound signals to the outside of the electronic device 101. The sound output module 155 may include, for example, a speaker or a receiver. The speaker may be used for general purposes, such as playing multimedia or playing record. The receiver may be used for receiving incoming calls. According to an embodiment, the receiver may be implemented as separate from, or as part of the speaker.

The display module 160 may visually provide information to the outside (e.g., a user) of the electronic device 101. The display module 160 may include, for example, a display, a hologram device, or a projector and control circuitry to control a corresponding one of the display, hologram device, and projector. According to an embodiment, the display module 160 may include a touch sensor adapted to detect a touch, or a pressure sensor adapted to measure the intensity of force incurred by the touch.

The audio module 170 may convert a sound into an electrical signal and vice versa. According to an embodiment, the audio module 170 may obtain the sound via the input module 150, or output the sound via the sound output module 155 or a headphone of an external electronic device (e.g., an electronic device 102) directly (e.g., wiredly) or wirelessly coupled with the electronic device 101.

The sensor module 176 may detect an operational state (e.g., power or temperature) of the electronic device 101 or an environmental state (e.g., a state of a user) external to the electronic device 101, and then generate an electrical signal or data value corresponding to the detected state. According to an embodiment, the sensor module 176 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly (e.g., wiredly) or wirelessly. According to an embodiment, the interface 177 may include, for example, a high definition multimedia interface (HDMI), a universal serial bus (USB) interface, a secure digital (SD) card interface, or an audio interface.

A connecting terminal 178 may include a connector via which the electronic device 101 may be physically connected with the external electronic device (e.g., the electronic device 102). According to an embodiment, the connecting terminal 178 may include, for example, a HDMI connector, a USB connector, a SD card connector, or an audio connector (e.g., a headphone connector).

The haptic module 179 may convert an electrical signal into a mechanical stimulus (e.g., a vibration or a movement) or electrical stimulus which may be recognized by a user via his tactile sensation or kinesthetic sensation. According to an embodiment, the haptic module 179 may include, for example, a motor, a piezoelectric element, or an electric stimulator.

The camera module 180 may capture a still image or moving images. According to an embodiment, the camera module 180 may include one or more lenses, image sensors, image signal processors, or flashes.

The power management module 188 may manage power supplied to the electronic device 101. According to an embodiment, the power management module 188 may be implemented as at least part of, for example, a power management integrated circuit (PMIC).

The battery 189 may supply power to at least one component of the electronic device 101. According to an embodiment, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more communication processors that are operable independently from the processor 120 (e.g., the application processor (AP)) and supports a direct (e.g., wired) communication or a wireless communication. According to an embodiment, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). A corresponding one of these communication modules may communicate with the external electronic device via the first network 198 (e.g., a short-range communication network, such as Bluetooth™ wireless-fidelity (Wi-Fi) direct, or infrared data association (IrDA)) or the second network 199 (e.g., a long-range communication network, such as a legacy cellular network, a 5G network, a next-generation communication network, the Internet, or a computer network (e.g., LAN or wide area network (WAN)). These various types of communication modules may be implemented as a single component (e.g., a single chip), or may be implemented as multi components (e.g., multi chips) separate from each other. The wireless communication module 192 may identify and authenticate the electronic device 101 in a communication network, such as the first network 198 or the second network 199, using subscriber information (e.g., international mobile subscriber identity (IMSI)) stored in the subscriber identification module 196.

The wireless communication module 192 may support a 5G network, after a 4G network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 192 may support a high-frequency band (e.g., the mmWave band) to achieve, e.g., a high data transmission rate. The wireless communication module 192 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 192 may support various requirements specified in the electronic device 101, an external electronic device (e.g., the electronic device 104), or a network system (e.g., the second network 199). According to an embodiment, the wireless communication module 192 may support a peak data rate (e.g., 20 Gbps or more) for implementing eMBB, loss coverage (e.g., 164 dB or less) for implementing mMTC, or U-plane latency (e.g., 0.5 ms or less for each of downlink (DL) and uplink (UL), or a round trip of 1 ms or less) for implementing URLLC.

The antenna module 197 may transmit or receive a signal or power to or from the outside (e.g., the external electronic device) of the electronic device 101. According to an embodiment, the antenna module 197 may include an antenna including a radiating element including a conductive material or a conductive pattern formed in or on a substrate (e.g., a printed circuit board (PCB)). According to an embodiment, the antenna module 197 may include a plurality of antennas (e.g., array antennas). In such a case, at least one antenna appropriate for a communication scheme used in the communication network, such as the first network 198 or the second network 199, may be selected, for example, by the communication module 190 (e.g., the wireless communication module 192) from the plurality of antennas. The signal or the power may then be transmitted or received between the communication module 190 and the external electronic device via the selected at least one antenna. According to an embodiment, another component (e.g., a radio frequency integrated circuit (RFIC)) other than the radiating element may be additionally formed as part of the antenna module 197.

According to various embodiments, the antenna module 197 may form a mmWave antenna module. According to an embodiment, the mmWave antenna module may include a printed circuit board, a RFIC disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 101 and the external electronic device 104 via the server 108 coupled with the second network 199. Each of the electronic devices 102 or 104 may be a device of a same type as, or a different type, from the electronic device 101.

According to an embodiment, all or some of operations to be executed at the electronic device 101 may be executed at one or more of the external electronic devices 102, 104, or 108. For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, mobile edge computing (MEC), or client-server computing technology may be used, for example. The electronic device 101 may provide ultra low-latency services using, e.g., distributed computing or mobile edge computing. In an embodiment, the external electronic device 104 may include an internet-of-things (IoT) device. The server 108 may be an intelligent server using machine learning and/or a neural network. According to an embodiment, the external electronic device 104 or the server 108 may be included in the second network 199. The electronic device 101 may be applied to intelligent services (e.g., smart home, smart city, smart car, or healthcare) based on 5G communication technology or IoT-related technology.

The electronic device according to various embodiments may be one of various types of electronic devices. The electronic devices may include, for example, a portable communication device (e.g., a smartphone), a computer device, a portable multimedia device, a portable medical device, a camera, a wearable device, a home appliance, or the like. According to an embodiment of the disclosure, the electronic devices are not limited to those described above.

It should be appreciated that various embodiments of the present disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), the element may be coupled with the other element directly (e.g., wiredly), wirelessly, or via a third element.

As used in connection with various embodiments of the disclosure, the term “module” may include a unit implemented in hardware, software, or firmware, or any combination thereof, and may interchangeably be used with other terms, for example, “logic,” “logic block,” “part,” or “circuitry”. A module may be a single integral component, or a minimum unit or part thereof, adapted to perform one or more functions. For example, according to an embodiment, the module may be implemented in a form of an application-specific integrated circuit (ASIC).

According to various embodiments, each component (e.g., a module or a program) of the above-described components may include a single entity or multiple entities, and some of the multiple entities may be separately disposed in different components. According to various embodiments, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

The term “on” as used herein is not limited to being “directly on” or “contacting” and may include being “on” an element with another element or space in between.

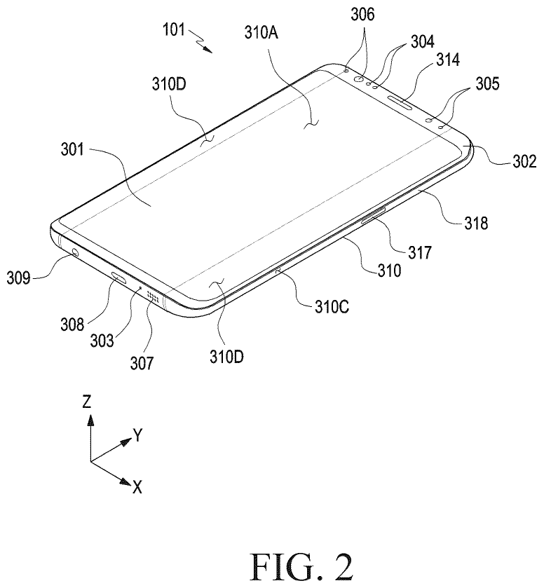

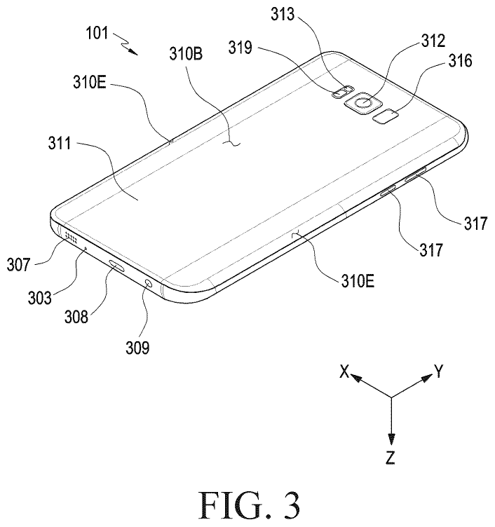

FIG. 2 is a front side perspective view illustrating an example electronic device 101 according to various embodiments. FIG. 3 is a rear perspective view illustrating the electronic device 101 according to various embodiments.

Referring to FIGS. 2 and 3, the electronic device 101 according to an embodiment may include a housing 310 including a first surface (or a front surface) 310A, a second surface (or a rear surface) 310B, and a side surface 310C surrounding the space between the first surface 310A and the second surface 310B. In an embodiment (not illustrated), the housing 310 may refer to a structure that provides some of the first surface 310A, the second surface 310B, and the side surface 310C of FIG. 2. According to an embodiment, at least a portion of the first surface 310A may be defined by a substantially transparent front surface plate 302 (e.g., a glass plate or a polymer plate with various coating layers). The second surface 310B may be provided by a substantially opaque rear surface plate 311. The rear surface plate 311 may be made of, for example, coated or colored glass, ceramic, polymer, metal (e.g., aluminum, stainless steel (STS), or magnesium), or a combination of two or more of these materials. The side surface 310C may be defined by a side surface bezel structure (or a “side surface member”) 318 coupled to the front surface plate 302 and the rear surface plate 311 and including metal and/or polymer. In various embodiments, the rear surface plate 311 and the side surface bezel structure 318 may be integrally configured and may include the same material (e.g., a metal material such as aluminum).

In the illustrated embodiment, the front surface plate 302 may include, at the long opposite side edges thereof, two first areas 310D, which are bent from the first surface 310A toward the rear surface plate 311 and extend seamlessly. In the illustrated embodiment (see FIG. 3), the rear surface plate 311 may include, at the long opposite side edges thereof, two second areas 310E, which are bent from the second surface 310B toward the front surface plate 302 and extend seamlessly. In various embodiments, the front surface plate 302 (or the rear surface plate 311) may include only one of the first areas 310D (or the second areas 310E). In an embodiment, some of the first areas 310D or the second areas 310E may not be included. In the above-described embodiments, when viewed from a side of the electronic device 101, the side surface bezel structure 318 may have a first thickness (or width) on the side where the first areas 310D or the second areas 310E are not included, and may have a second thickness, which is smaller than the first thickness, on the side where the first areas 310D or the second areas 310E are included.

According to an embodiment, the electronic device 101 may include at least one of a display 301, audio modules 303, 307, and 314, sensor modules 304, 316, and 319, camera modules 305, 312, and 313, key input devices 317, light-emitting elements 306, and connector holes 308 and 309. In various embodiments, at least one of the components (e.g., the key input devices 317 or the light-emitting elements 306) may be omitted from the electronic device 101, or other components may be additionally included in the electronic device 200.

According to an embodiment, the display 301 may be visible through a substantial portion of, for example, the front plate 302. In various embodiments, at least a portion of the display 301 may be visible through the front surface plate 302, which defines the first surface 310A and the first areas 310D of the side surface 310C. In various embodiments, the edges of the display 301 may be configured to be substantially the same as the shape of the periphery of the front surface plate 302 adjacent thereto. In an embodiment (not illustrated), the distance between the periphery of the display 301 and the periphery of the front surface plate 302 may be substantially constant in order to enlarge the visible area of the display 301.

In an embodiment (not illustrated), recesses or openings may be provided in a portion of the screen display area of the display 301, and one or more of the audio modules 314, the sensor modules 304, the camera modules 305, and the light-emitting elements 306, which are aligned with the recesses or the openings, may be included. In an embodiment (not illustrated), the rear surface of the screen display area of the display 301 may include at least one of the audio module 314, the sensor modules 304, the camera modules 305, a fingerprint sensor 316, and the light-emitting elements 306. In an embodiment (not illustrated), the display 301 may be coupled to or disposed adjacent to a touch-sensitive circuit, a pressure sensor capable of measuring a touch intensity (pressure), and/or a digitizer configured to detect an electromagnetic field-type stylus pen. In various embodiments, at least some of the sensor modules 304 and 319 and/or at least some of the key input devices 317 may be disposed in the first areas 310D and/or the second areas 310E.

According to an embodiment, the audio modules 303, 307, and 314 may include a microphone hole 303 and speaker holes 307 and 314. The microphone hole 303 may include a microphone disposed therein to acquire external sound, and in various embodiments, multiple microphones may be disposed therein to be able to detect the direction of sound. The speaker holes 307 and 314 may include an external speaker hole 307 and a communication receiver hole 314. In various embodiments, the speaker holes 307 and 314 and the microphone hole 303 may be implemented as a single hole, or a speaker (e.g., a piezo speaker) may be included without the speaker holes 307 and 314.

According to an embodiment, the sensor modules 314, 316, and 319 may generate electrical signals or data values corresponding to an internal operating state or an external environmental state of the electronic device 101. The sensor modules 304, 316, and 319 may include, for example, a first sensor module 304 (e.g., a proximity sensor), a second sensor module (not illustrated) (e.g., a fingerprint sensor) disposed on the first surface 310A of the housing 310, a third sensor module 319 (e.g., an HRM sensor), and/or a fourth sensor module 316 (e.g., a fingerprint sensor) disposed on the second surface 310B of the housing 310. The fingerprint sensor may be disposed not only on the front surface 310A of the housing 310 (e.g., the display 301), but also on the rear surface 310B. The electronic device 101 may further include at least one of sensor modules (not illustrated), such as a gesture sensor, a gyro sensor, an atmospheric pressure sensor, a magnetic sensor, an acceleration sensor, a grip sensor, a color sensor, an infrared (IR) sensor, a biometric sensor, a temperature sensor, a humidity sensor, or an illuminance sensor 304.

According to an embodiment, the camera modules 305, 312, and 313 may include a first camera device 305 disposed on the first surface 310A of the electronic device 101, and a second camera device 312 and/or a flash 313 disposed on the second surface 310B. The camera modules 305 and 312 may include one or more lenses, an image sensor, and/or an image signal processor. The flash 313 may include, for example, a light-emitting diode or a xenon lamp. In various embodiments, two or more lenses (e.g., an infrared camera, a wide-angle lens, and a telephoto lens), and image sensors may be arranged on one surface of the electronic device 101.

According to an embodiment, the key input devices 317 may be disposed on the side surface 310C of the housing 310. In an embodiment, the electronic device 101 may not include some or all of the above-mentioned key input devices 317, and the key input devices 317, which are not included, may be implemented in another form, such as soft keys, on the display 301. In various embodiments, the key input devices 317 may include a sensor module 316 disposed on the second surface 310B of the housing 310.

According to an embodiment, the light-emitting element 306 may be disposed on, for example, the first surface 310A of the housing 310. The light-emitting element 306 may provide, for example, the state information of the electronic device 101 in an optical form. In an embodiment, the light-emitting element 306 may provide a light source that is operationally linked with, for example, the operation of the camera module 305. The light-emitting element 306 may include, for example, an LED, an IR LED, and a xenon lamp.

According to an embodiment, the connector holes 308 and 309 may include a first connector hole 308 capable of accommodating a connector (e.g., a USB connector) configured to transmit/receive power and/or data to/from an external electronic device, and/or a second connector hole 309 capable of accommodating a connector (e.g., an earphone jack) configured to transmit/receive audio signals to/from an external electronic device.

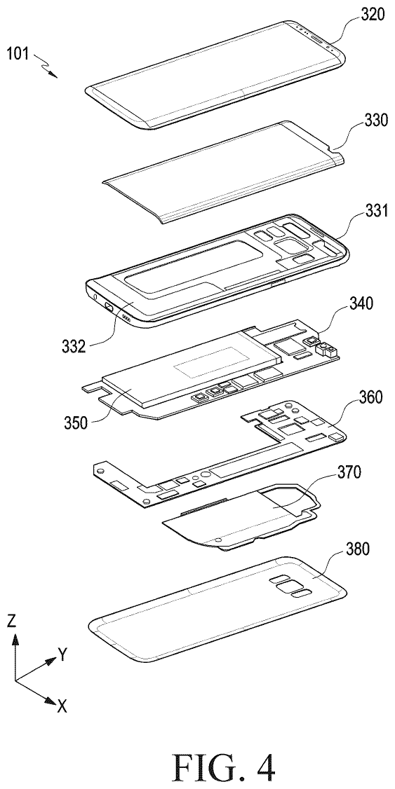

FIG. 4 is an exploded perspective view of an electronic device 101 according to various embodiments.

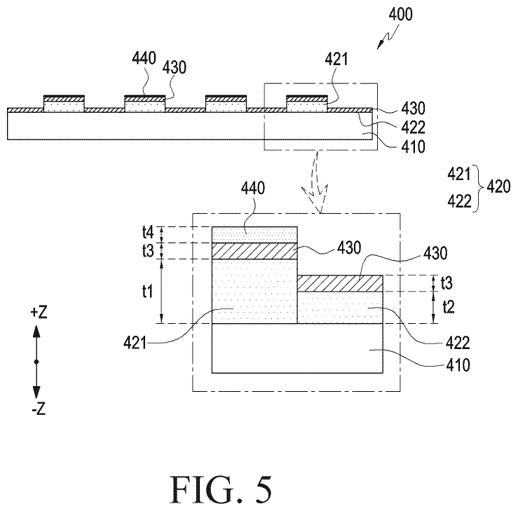

Referring to FIG. 4, an electronic device 101 (e.g., the electronic device 101 in FIGS. 1 to 4) may include a side surface bezel structure 331, a first support member 332 (e.g., a bracket), a front surface plate 320, a display 330, a printed circuit board 340, a battery 350, a second support member 360 (e.g., a rear case), an antenna 370, and a rear surface plate 380. In various embodiments, at least one of the components (e.g., the first support member 332 or the second support member 360) may be omitted from the electronic device 101, or other components may be additionally included in the electronic device 101. At least one of the components of the electronic device 101 may be the same as or similar to at least one of the components of the electronic device 101 of FIG. 4 or FIG. 5, and a redundant description thereof may not be repeated below.

According to an embodiment, the first support member 332 may be disposed inside the electronic device 101 to be connected to the side surface bezel structure 331, or may be formed integrally with the side surface bezel structure 331. The first support member 332 may be made of, for example, a metal material and/or a non-metal (e.g., polymer) material. The first support member 332 may have one surface to which the display 330 is coupled, and the other surface to which the printed circuit board 340 is coupled. A processor, memory, and/or an interface may be mounted on the printed circuit board 340. The processor may include, for example, one or more of a central processing unit, an application processor, a graphics processing unit, an image signal processor, a sensor hub processor, or a communication processor.

According to an embodiment, the memory may include, for example, volatile memory or nonvolatile memory.

According to an embodiment, the interface may include, for example, a high-definition multimedia interface (HDMI), a universal serial bus (USB) interface, an SD card interface, and/or an audio interface. For example, the interface may electrically or physically connect the electronic device 101 to an external electronic device, and include a USB connector, an SD card/MMC connector, or an audio connector.

According to an embodiment, the battery 350 is a device that supplies power to at least one component of the electronic device 101, and may include, for example, a non-rechargeable primary battery, a rechargeable secondary battery, or a fuel cell. At least a portion of the battery 350 may be disposed on substantially the same plane as, for example, the printed circuit board 340. The battery 350 may be integrally disposed inside the electronic device 101 or may be detachably disposed on the electronic device 101.

According to an embodiment, the antenna 370 may be disposed between the rear surface plate 380 and the display 350. The antenna 370 may include, for example, a near-field communication (NFC) antenna, a wireless charging antenna, and/or a magnetic secure transmission (MST) antenna. For example, the antenna 370 may execute short-range communication with an external device or may transmit/receive power required for charging to/from an external device in a wireless manner. In an embodiment, an antenna structure may be configured by a portion of the side surface bezel structure 331 and/or the first support member 332, or a combination thereof.

According to an embodiment of the disclosure, the electronic device may include multiple antenna modules 390. For example, some of the multiple antenna modules 390 may be implemented in order to transmit and receive radio waves having different characteristics (provisionally referred to as radio waves of frequency bands A and B) for MIMO implementation. As another example, some of the multiple antenna modules 390 may be configured, for example, to simultaneously transmit and receive radio waves having the same characteristics (provisionally referred to as radio waves having frequencies A1 and A2 in the frequency band A) for the purpose of diversity implementation. As another example, the remaining antenna modules 390 may be configured, for example, to simultaneously transmit and receive radio waves having the same characteristics (provisionally referred to as radio waves having frequencies B1 and B2 in the frequency band B) for diversity implementation. In an embodiment of the disclosure, the electronic device 101 may include two antenna modules, but in an embodiment of the disclosure, the electronic device 101 may include four antenna modules so as to simultaneously implement MIMO and diversity. In still an embodiment, the electronic device 101 may include only one antenna module 390.

According to an embodiment, in consideration of the transmission/reception characteristics of radio waves, when one antenna module is disposed at a first position on the printed circuit board 340, another antenna module may be disposed at a second position, which is separated from the first position on the printed circuit board 340. As another example, one antenna module and another antenna module may be arranged in consideration of the mutual separation distance between the one antenna module and the another antenna module according to a diversity characteristic.

According to an embodiment, at least one antenna module 390 may include a wireless communication circuit that processes radio waves transmitted/received in an ultra-high-frequency band (e.g., 6 GHz or higher and 300 GHz or lower). A conductive plate of the at least one antenna module 390 may include, for example, a patch-type radiation conductor or a conductive plate having a dipole structure extending in one direction. Multiple conductive plates may be arrayed to form an antenna array. For example, a chip in which a part of the wireless communication circuit is implemented (e.g., an integrated circuit chip) may be disposed on one side of the area in which the conductive plate is disposed or on the surface that faces away from the surface on which the conductive plate is disposed, and may be electrically connected to the conductive plate via wiring made of a printed circuit pattern.

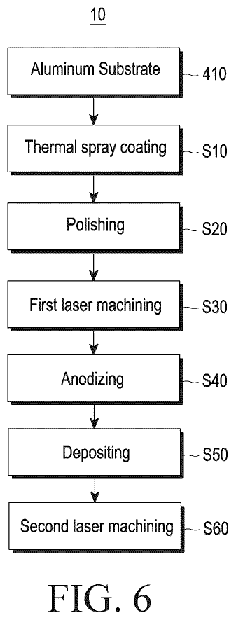

According to an embodiment, at least one of the housing 310, the support member (e.g., the first support member 332 and/or the second support member 360), the side surface bezel structure 331, the front surface plate 320, and/or the rear surface plate 380 of the electronic device 101 may include, at least partially, a metallic material. For example, at least a portion of the housing 310, the support member (e.g., the first support member 332 and/or the second support member 360), the side surface bezel structure 331, the front surface plate 320, and/or the rear surface plate 380 of the electronic device 101 may be manufactured by the housing manufacturing process 10 of FIG. 6, which will be described later. In the illustrated embodiment, the housing 310, the support member (e.g., the first support member 332 and/or the second support member 360), the side surface bezel structure 331, the front surface plate 320, and/or the rear surface plate 380 may be at least partially visible from the exterior of the electronic device 101.

FIG. 5 is a cross-sectional view illustrating a cross-section of a housing 400 according to various embodiments.

Referring to FIG. 5, the housing 400 of the electronic device 101 may include an aluminum substrate 410, a thermal spray coating layer 420, an oxide film layer 430, and a deposition film layer 440. Referring to FIG. 5, the configuration of the housing 400 may be entirely or partially identical to the configuration of the housing 310 shown in FIGS. 2 through 4. The components in FIG. 5 may be selectively combined with the components in FIGS. 2 to 4.

According to FIG. 5, a spatial coordinate system defined by the Z-axis is illustrated. The Z-axis may represent the thickness direction of the housing 400.

According to an embodiment, the housing 400 of the electronic device may refer to a structure defining some of the first surface 310A, second surface 310B, and side surface 310C illustrated in FIGS. 2 and 3. For example, the housing 400 of the electronic device may refer to a structure that defines a portion of the second surface (or rear surface) 310B illustrated in FIG. 2. According to an embodiment, the housing 400 may be defined by a substantially opaque rear surface plate (e.g., the rear surface plate 311 in FIG. 2). The rear surface plate may be made of, for example, coated or colored glass, ceramics, polymer, metal (e.g., aluminum, stainless steel (STS), or magnesium), or a combination of at least two of these materials. The rear surface plate may be made of, for example, metal (e.g., aluminum, stainless steel (STS), or magnesium). The rear surface plate may be made of, for example, aluminum metal.

According to an embodiment, the housing 400 may include a metallic substrate. The metallic substrate may include, for example, a metal material such as aluminum, stainless steel, titanium, or magnesium.

According to a general electronic device, the housing may be made of a high-gloss metallic material. The high-gloss metallic material may be, for example, a metal such as titanium (Ti) or stainless steel (STS). High-gloss metallic materials such as titanium (Ti) and stainless steel (STS) may be hard-to-cut metallic materials which are highly rigid and difficult to machine. High-gloss metallic materials may be heavy and difficult to machine, which increase production costs, and may have limitations in achieving diverse surface textures.

In general electronic devices, high-gloss metallic materials may be directly used and processed by methods such as deposition or anodizing, to achieve various surface textures. To this end, materials may be processed, or powder metallurgy using powders or 3D printing technology may be utilized. However, when high-gloss metallic materials are used directly, the characteristics of the materials may result in high material costs and significant processing costs due to the difficulty of processing. When anodizing is performed, a thin coating layer formed due to aluminum (Al₂O₃) (e.g., less than a micron) may make it difficult to use for the exterior of an electronic device. When anodizing is performed, the thickness differences in the oxide film may lead to non-uniform surface colors.

In general electronic devices, various surface textures may be achieved by directly machining high-gloss metallic materials using a tool. However, the depth or thickness of a housing surface inevitably depends on the shape of the tool, and limitations in length may exist.

In general electronic devices, chemical etching may be applied to a high-gloss metallic housing surface to achieve various surface textures. However, in this case, depth control by location is not possible, which may limit the implementation of diverse textures.

In general electronic devices, surface textures may be implemented on a high-gloss metallic housing surface through physical impact to implement various surface textures. However, in this case, the shapes of the surface may be limited.

According to an embodiment of the disclosure, the housing 400 may include an aluminum substrate 410. The housing 400 may include an aluminum material instead of high-gloss metallic materials, such as titanium and stainless steel, which are difficult to machine and have limitations in post-treatment. The aluminum substrate 410 is commonly used in an electronic device housing 400 and may have a low specific gravity. The aluminum substrate 410 may be easy to machine and facilitate post-treatments such as deposition or anodizing.

According to an embodiment, the housing 400 may further include a thermal spray coating layer 420, an oxide film layer 430, and a deposition film layer 440, which are machined to provide the aluminum substrate 410 with a texture and/or gloss similar to high-gloss metallic materials.

According to an embodiment, the thermal spray coating layer 420 may be disposed on the aluminum substrate 410. According to an embodiment, the thermal spray coating layer 420 may include multiple areas with different thicknesses to achieve a desired design shape. According to an embodiment, the thermal spray coating layer 420 may include a first area 421 with a first thickness t1 and a second area 422 with a second thickness t2, which is smaller than the first thickness t1. The first thickness t1 may be, for example, about 5 μm or greater and 15 μm or less. The first thickness t1 may be, for example, about 10 μm. The second thickness t2 may be, for example, about m or less. The second thickness t2 may be, for example, about 3 μm or less. According to an embodiment, the thickness difference between the first area 421 and the second area 422 may be, for example, about 1 μm or greater and 5 μm or less. According to an embodiment, the thermal spray coating layer 420 may be formed on the aluminum substrate 410. In general electronic devices, a thermal spray process has been used to shield surfaces or prevent and/or reduce oxidation when rusting or cracking occurs, which weakens the rigidity of the surfaces. According to an embodiment of the disclosure, the thermal spray coating layer 420 may be formed on the housing 400 to implement an appearance surface similar to titanium or stainless steel. The thermal spray coating layer 420 may be formed on the housing 400 to implement a gloss similar to titanium or stainless steel.

According to an embodiment, the oxide film layer 430 may be disposed on the thermal spray coating layer 420 or the aluminum substrate 410. According to an embodiment, the oxide film layer 430 may be formed on the aluminum substrate 410. According to an embodiment, the thickness t3 of the oxide film layer 430 may be, for example, about 7 μm or greater and 10 μm or less. The thickness t3 of the oxide film layer 430 may be, for example, about 8 μm. According to an embodiment, the oxide film layer 430 may be formed on the housing 400 to implement a new texture and a sense of depth in color.

According to an embodiment, the deposition film layer 440 may be formed on the thermal spray coating layer 420. The deposition film layer 440 may be formed on at least a portion of the thermal spray coating layer 420. The deposition film layer 440 may be formed on the first area 421 of the thermal spray coating layer 420. According to an embodiment, the deposition film layer 440 may be formed on the oxide film layer 430. According to an embodiment, the thickness T4 of the deposition film layer 440 may be formed thin. The thickness t4 of the deposition film layer 440 may be, for example, about 2 μm or less. The thickness t4 of the deposition film layer 440 may be, for example, about 1 μm. According to an embodiment, the deposition film layer 440 may be formed on the thermal spray coating layer 420 to prevent and/or reduce corrosion of the thermal spray coating layer 420. According to an embodiment, the deposition film layer 440 may be formed on the thermal spray coating layer 420 to implement a desired color. According to an embodiment, as the deposition film layer 440 is formed on a portion of the housing 400, various designs and pattern shapes may be implemented.

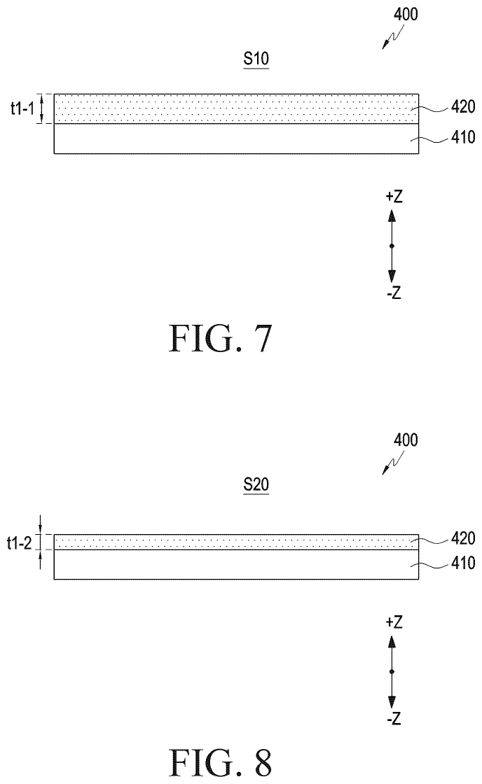

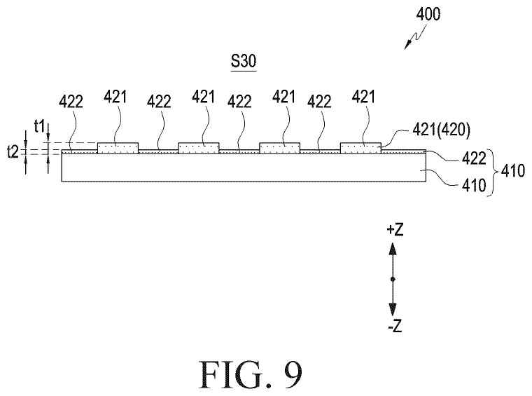

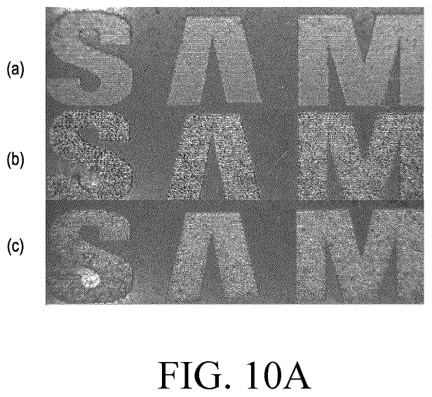

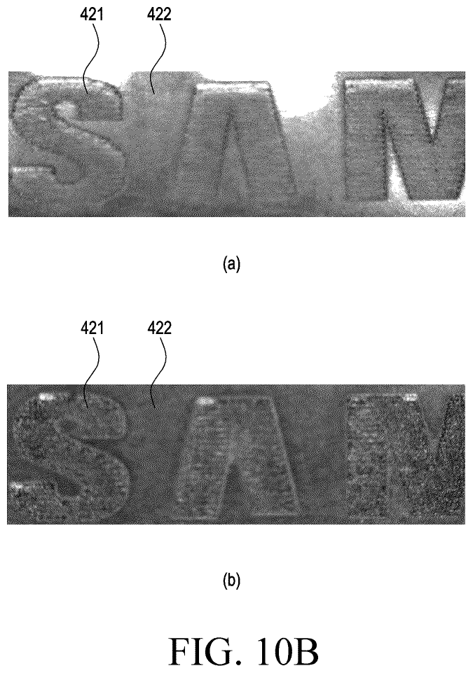

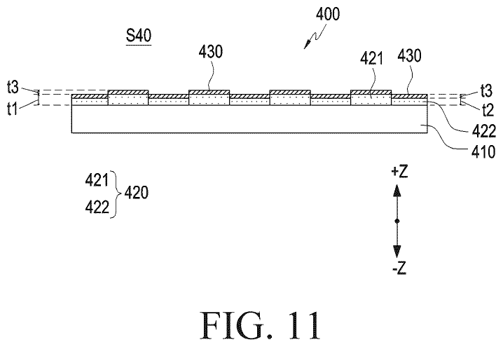

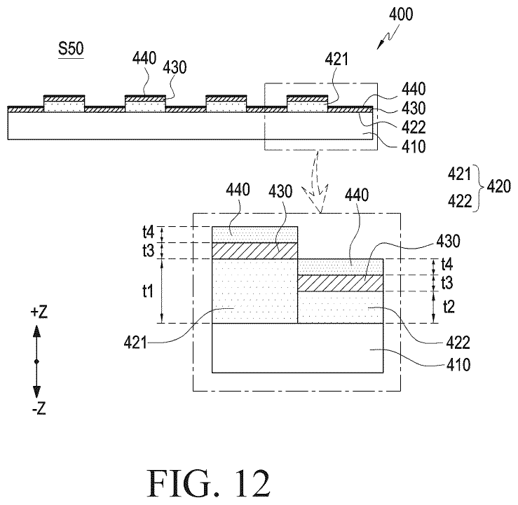

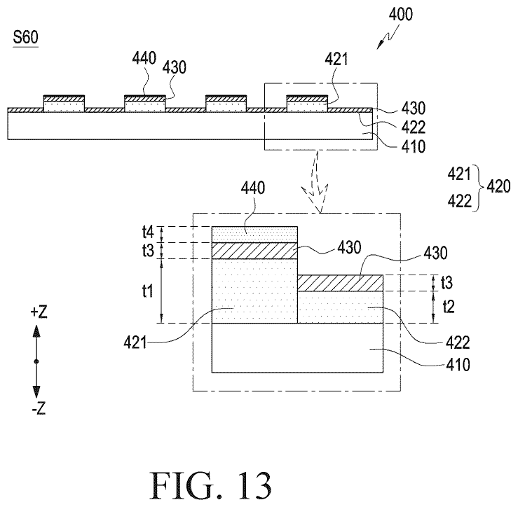

FIG. 6 is a flowchart illustrating an example housing 400 manufacturing method according to various embodiments. FIG. 7 is a cross-sectional view illustrating an example first process S10 in the example method of manufacturing the housing 400 according to various embodiments. FIG. 8 is a cross-sectional view illustrating an example second process S20 in the example method of manufacturing the housing 400 according to various embodiments. FIG. 9 is a cross-sectional view illustrating an example third process S30 in the example method of manufacturing the housing 400 according to various embodiments. FIG. 10A is a diagram illustrating brightness differences according to thickness differences in a thermal spray coating layer 420, according to various embodiments. FIG. 10B is a diagram illustrating gloss differences according to laser machining thickness differences according to various embodiments. FIG. 11 is a cross-sectional view illustrating an example fourth process S40 in the example method of manufacturing the housing 400 according to various embodiments. FIG. 12 is a cross-sectional view illustrating an example fifth process S50 in the example method of manufacturing the housing 400 according to various embodiments. FIG. 13 is a cross-sectional view illustrating an example sixth process S60 in the example method of manufacturing the housing 400 according to various embodiments.

Referring to FIGS. 6, 7, 8, 9, 10A, 10B, 11, 12 and 13 (which may be referred to as FIGS. 6 to 13), the housing 400 of the electronic device 101 may include an aluminum substrate 410, a thermal spray coating layer 420, an oxide film layer 430, and a deposition film layer 440. Referring to FIGS. 6 to 13, the configuration of the housing 400, the aluminum substrate 410, the thermal spray coating layer 420, the oxide film layer 430, and the deposition film layer 440 may be wholly or partially identical to the configuration of the housing 400, the aluminum substrate 410, the thermal spray coating layer 420, the oxide film layer 430, and the deposition film layer 440 of FIG. 5. The structures of FIGS. 6 to 13 may be optionally combined with the structure of FIG. 5.

According to FIGS. 6 to 13, a spatial coordinate system defined by the Z-axis is illustrated. The Z-axis may represent the thickness direction of the housing 400.

According to an embodiment, referring to FIG. 6, the housing 400 manufacturing method may include a first process S10 of performing thermal spray coating on the aluminum substrate 410, a second process S20 of polishing the thermal spray coating layer 420 formed on the aluminum substrate 410, a third process S30 of machining at least a portion of the thermal spray coating layer 420 using a laser, a fourth process S40 of forming the oxide film layer 430 through an anodizing process, a fifth process S50 of forming the deposition film layer 440 through a deposition process, and a sixth process S60 of machining at least a portion of the deposition film layer 440 using a laser. However, in the housing 400 manufacturing method, at least one of the processes may be omitted, or one or more additional processes may be included.

According to an embodiment, the housing 400 may use an aluminum (Al) substrate. Aluminum metal may be widely used as an exterior material for electronic devices.

According to an embodiment, referring to FIGS. 6 and 7, the first process S10 of forming the thermal spray coating layer 420 through thermal spray coating on the aluminum substrate 410 may be carried out. Thermal spray coating may be performed on the surface of the aluminum substrate 410. For example, plasma thermal spray coating may be performed on the surface of the aluminum substrate 410. The first process S10 may be a process in which, to achieve specific physical properties, a thermal spray material in powder or wire form is injected into a thermal spray device that generates a high-temperature heat source using gas, plasma, or laser, and the material is deposited onto the surface of the substrate by high-speed impact and lamination to form the thermal spray coating layer 420. Recently, thermal barrier coatings (TBCs) have been widely used in, for example, the aerospace field. The thermal spray material for plasma thermal spray coating may include, for example, metal, non-metal, or ceramic. The first process S10 may be a surface processing method in which a coating material in the form of powder or rod, possessing specific properties required for the surface, is melted or semi-melted using various heat sources such as plasma in an atmospheric or vacuum environment, and then sprayed at high speed to form the thermal spray coating layer 420. The coating material may be, for example, titanium dioxide (TiO₂) in powder form. For example, the surface of the aluminum substrate 410 may be coated with titanium dioxide (TiO₂) thermal spray powder.

According to an embodiment, the thickness t1-1 of the thermal spray coating layer 420 formed through the first process S10 may be, for example, about 200 μm or greater and 500 μm or less. Considering machining time and/or machining cost, it may be desirable for the thickness of the thermal spray coating layer 420 formed through thermal spray coating to be, for example, about 400 μm or less.

According to an embodiment, the thermal spray coating layer 420 may be formed on the aluminum substrate 410. In general electronic devices, a thermal spray process has been used to shield surfaces or prevent and/or reduce oxidation when rusting or cracking occurs, which weakens the rigidity of the surfaces. According to an embodiment of the disclosure, the thermal spray coating layer 420 may be formed on the housing 400 to implement an appearance surface similar to titanium or stainless steel. The thermal spray coating layer 420 may be formed on the housing 400 to implement a gloss similar to titanium or stainless steel.

According to an embodiment, referring to FIGS. 6 and 8, the second process S20 of polishing the thermal spray coating layer 420 formed on the aluminum substrate 410 may be performed. According to an embodiment, the second process (polishing process) S20 may be used to smoothly polish the surface of the thermal spray coating layer 420. Through the second process (polishing process) S20, the surface finish of the thermal spray coating layer 420 may be formed. The second process (polishing process) S20 may include cleaning the surface using an abrasive material or, when the abrasive material is thick, machining the surface of the thermal spray coating layer 420 with the abrasive material after machining the surface with a cutting tool.

According to an embodiment, the thickness t1-2 of the thermal spray coating layer 420 machined through the second process S20 may be, for example, about 10 μm or greater and 30 μm or less. The thickness t1-2 of the thermal spray coating layer 420 machined through the second process S20 may be, for example, about 20 μm. However, in the housing 400 manufacturing method, the second process S20 may be omitted depending on the implementation conditions and design method.

According to an embodiment, referring to FIGS. 6 and 9, a third process (laser process) S30 of machining at least a portion of the thermal spray coating layer 420 using a laser may be performed. The third process (laser process) S30 may aim to implement a desired design shape on the polished housing 400. In order to implement a desired design shape on the housing 400, at least a portion of the thermal spray coating layer 420 may be locally machined using a laser to form multiple areas with different thicknesses. Differences in thickness may cause brightness differences in color, enabling the implementation of a desired design shape.

According to an embodiment, after the third process (laser process) S30, the thermal spray coating layer 420 may include a first area 421 with a first thickness t1 and a second area 422 with a second thickness t2, which is smaller than the first thickness t1. The first thickness t1 may be, for example, about 5 μm or greater and 15 μm or less. The first thickness t1 may be, for example, about 10 μm. The second thickness t2 may be, for example, about 5 μm or less. The second thickness t2 may be, for example, about 3 μm or less. Laser equipment may vary depending on the cutting thickness. For example, when the cutting thickness is less than 1 μm, a UV laser may be used. For example, when the cutting thickness is about 1 μm or greater and 5 μm, an IR laser may be used. According to an embodiment, the thickness difference between the first area 421 and the second area 422 may be, for example, about 1 μm or greater and 5 μm or less.

According to an embodiment, the second thickness t2 may include 0 μm. The thermal spray coating layer 420 may include only the first area 421 with the first thickness t1 formed on at least a portion of the aluminum substrate 410.

According to an embodiment, FIG. 10A illustrates photographs comparing brightness differences caused by cutting thickness differences between the first areas 421 and the second areas 422. In FIG. 10A(a), the brightness difference is shown when the thickness difference between the first thickness t1 of the first area 421 and the second thickness t2 of the second area 422 is about 1 μm or less. In FIG. 10A(b), the brightness difference is shown when the thickness difference between the first thickness t1 of the first area 421 and the second thickness t2 of the second area 422 is about 1 μm or greater and 3 μm or less. In FIG. 10A(c), the brightness difference is shown when the cutting thickness difference between the first thickness t1 of the first area 421 and the second thickness t2 of the second area 422 is about 3 μm or greater and 5 μm or less. As the transition progresses from (a) to (c), it may be observed that increasing thickness differences result in greater and more distinct bright differences.

According to an embodiment, FIG. 10B illustrates photographs comparing gloss value differences resulting from laser machining thickness differences between the first areas 421 and the second areas 422. The first thickness t1 of the first area 421 in FIG. 10B(a) and that in FIG. 10B(b) may be the same. The gloss values of the first areas 421 in FIG. 10B(a) and FIG. 10B(b) may be 0.8. The second thickness t2 of the second area 422 in FIG. 10B(a) and that in FIG. 10B(b) may differ, resulting in a gloss value difference. The second thickness t2 of the second area 422 in FIG. 10B(b) may be relatively greater than that in FIG. 10B(a). The gloss value of the second area 422 in FIG. 10B(a) may be 25. The gloss value of the second area 422 in FIG. 10B(b) may be 17. The difference in gloss value between the second area 422 and the first area 421 may be greater in FIG. 10B(a), where the thickness difference is relatively greater, than in FIG. 10B(b), where the thickness difference is relatively smaller.

According to an embodiment, referring to FIG. 11, the fourth process S40 of forming the oxide film layer 430 through an anodizing process may be performed. The fourth process S40 may implement new textures and colors with a sense of depth. According to an embodiment, the oxide film layer 430 may be formed on the thermal spray coating layer 420 and/or the aluminum substrate 410. According to an embodiment, the oxide film layer 430 may be formed on the aluminum substrate 410. According to an embodiment, anodizing may be performed on first areas 421 of the thermal spray coating layer 420 and second areas 422, which have a thickness different from that of the first areas 421. For manufacturing convenience, anodizing may be performed on the oxide film layer 430 and the aluminum substrate 410. However, the oxide film layer 430 formed on the aluminum substrate 410 is of substantial significance. Anodizing refers to an anodic oxidation process and may be a process for electrochemically forming an oxide film using a metal as to be plated as an anode. For example, anodizing may be widely used as post-treatment for aluminum surfaces. The anodizing process may broadly be divided into a pretreatment stage, an anodizing stage, a dyeing stage, and a post-treatment stage. However, each stage of the anodizing process may be omitted as necessary.

According to an embodiment, the pretreatment stage may include processes such as degreasing and desmutting. The degreasing process may be performed to remove contaminants such as stains on the product. The degreasing process may selectively apply a degreasing solution that is acidic or neutral, depending on the situation. The desmutting process may be performed to remove, from the surface of the material, smut and foreign substances that occur during the degreasing process.

According to an embodiment, after the pretreatment stage, the surface of the aluminum substrate 410 may undergo anodizing. In the anodizing stage, voltage may be applied to the aluminum substrate 410 to induce a reaction with oxygen, forming a dense oxide film. The anodized film may grow vertically depending on the shape of the base material. For example, in the case of a high-gloss surface, the film may also grow smoothly.

According to an embodiment, a dyeing process may be performed after the anodizing. The dyeing process may be a process for imparting color to the anodized oxide film. The dyeing process may include methods such as immersion, electrolytic dyeing, and/or oil dyeing. The immersion method may be a method of implementing color by immersing a product in a solution containing dissolved dyes and imparting color through the diffusion and adsorption of the dyes. The electrolytic dyeing method may be a method of causing coloration by applying an electric current to a metal salt electrolyte. The oil dyeing method may be a coloring method in which an oxide film is sensitized, dried, and then oil-based dye is applied with a brush. The types of dyes used in the immersion method may include both organic and inorganic dyes, and since the dyes used in the immersion method are primarily water-soluble, the immersion method may also be referred to as a water-based method. The dyeing process may allow the implementation of desired colors.

According to an embodiment, a post-treatment stage may be performed after the dyeing process. In the post-treatment stage, film pore sealing treatment and post-sealing treatment may be performed. The pore sealing treatment may include treatment using metal salts, treatment using non-metallic salts made of organic materials, and hydration pore sealing treatment using water and steam. The post-sealing treatment may include an elution process for removing metal salts and a hot water washing process for cleaning foreign substances. The post-treatment stage may be performed to ensure the stability and reliability of the appearance of materials that have undergone anodizing and dyeing.

According to an embodiment, the thickness t3 of the oxide film layer 430 formed through the fourth process S40 may be, for example, about 7 μm or greater and 10 μm or less. The thickness t3 of the oxide film layer 430 may be, for example, about 8 μm.

According to an embodiment, referring to FIG. 12, the fifth process S50 of forming the deposition film layer 440 through a deposition process may be performed. The deposition process refers to a process of heating and/or evaporating metal in a vacuum state and depositing the vapor as a thin film on the surface of an object. In general, the deposition process may be used for lens coating, film formation for electronic components, semiconductors, and the like. The deposition process may broadly include physical vapor deposition (PVD) and chemical vapor deposition (CVD). PVD refers to a deposition method that does not involve chemical reactions. PVD, which may be physical vapor deposition, is a technology in which materials for a thin film to be deposited are evaporated or sputtered in a vacuum and deposited onto a substrate. The materials may be heated in a vacuum using thermal energy or evaporated by heating the deposition material with an electron beam instead of heat. CVD refers to a method of deposition using particles or molecules in the form of gas formed through chemical reactions.

According to an embodiment, the fifth process S50 may be performed using a sputtering PVD deposition process, in which high-energy particles are made to collide with a deposition substrate. The sputtering PVD deposition process may be performed in a vacuum state. The deposition substrate may be connected to the anode (+), and a sample (target) substrate may be connected to the cathode (−). Then, an inert gas (e.g., argon (Ar)) is introduced, and a high voltage is applied. At this time, electrons are emitted from the cathode and accelerated toward the anode, colliding with the inert gas. As a result of the collision, the inert gas (Ar) is ionized into Ar+ and collides with the sample substrate, which is the cathode (−). The collision of the ionized inert gas (Ar+) with the sample substrate causes atoms present in the sample substrate to be ejected, and these atoms are deposited onto the substrate, forming a thin film. The sample substrate may be, for example, a metal substrate such as titanium (Ti), silicon (Si), or aluminum (Al).

According to an embodiment, the deposition film layer 440 may be formed on the thermal spray coating layer 420. The deposition film layer 440 may be formed on at least a portion of the thermal spray coating layer 420. The deposition film layer 440 may be formed on the first area 421 of the thermal spray coating layer 420. According to an embodiment, the deposition film layer 440 may be formed on the oxide film layer 430. According to an embodiment, the deposition film layer 440 may be formed on the thermal spray coating layer 420 to prevent and/or reduce corrosion of the thermal spray coating layer 420. According to an embodiment, the deposition film layer 440 may be formed on the thermal spray coating layer 420 to implement a desired color.

According to an embodiment, the thickness t4 of the deposition film layer 440 formed through the fourth process S40 may be thin. The thickness t4 of the deposition film layer 440 formed through the fourth process S40 may be, for example, about 2 μm or less. The thickness t4 of the deposition film layer 440 may be, for example, about 1 μm.

According to an embodiment, referring to FIG. 13, the sixth process S60 of machining at least a portion of the deposition film layer 440 using a laser may be performed. According to an embodiment, the sixth process S60 may remove the deposition film layer 440 formed on the second area 422 of the thermal spray coating layer 420. Laser equipment may vary depending on the cutting thickness. For example, when the cutting thickness is about 1 μm or less, a UV laser may be used. For example, when the cutting thickness is about 1 μm or greater and 5 μm, an IR laser may be used. According to an embodiment, the laser process of the sixth process S60 may use a UV laser. According to an embodiment, the thickness cut by the sixth process S60 may be about 3 μm or less. The thickness cut by the sixth process S60 may be, for example, about 1 μm or greater and 2 μm or less. The laser process may use a UV laser. According to an embodiment, the oxide film layer 430 may not be removed through the sixth process S60. According to an embodiment, various designs and pattern shapes may be implemented through the sixth process S60.

According to an embodiment, the machining depth of the final housing 400 may be, for example, about 5 μm or greater and 30 μm or less. However, the machining depth of the final housing 400 may vary depending on the required depth changes. By adjusting the machining depth and width, various textures may be achieved.

The housing 400 of the electronic device may include, for example, metallic materials such as aluminum, stainless steel, titanium, or magnesium. Among these, a housing 400 made of high-rigid and hard-to-cut materials such as titanium or stainless steel may enable the implementation of a high-gloss surface. However, high-rigid and hard-to-cut materials like titanium and stainless steel may have drawbacks, such as heavy weight, difficulty in machining that increases costs, and limitations in achieving diverse surface textures.

The housing 400 of an electronic device according to an embodiment of the disclosure may include aluminum material, which may help address conventional problems and implementing a novel and differentiated exterior design by diversifying the post-treatment functions of the exterior.

According to an embodiment of the disclosure, the housing 400 including an aluminum material may be machined to form a surface similar to that of hard-to-cut metallic materials like titanium and stainless steel and may implement new designs and textures through post-treatment methods such as polishing and laser machining.

According to an embodiment of the disclosure, the housing 400 may include an aluminum material instead of materials such as titanium and stainless steel, which are hard to machine and have limitations in post-treatment. The aluminum material may be machined into a housing 400 with a texture and/or gloss similar to titanium or stainless steel. Using aluminum material, post-treatment techniques that could not be implemented when using hard-to-cut materials like titanium or stainless steel may be applied.

However, the problems that the disclosure seeks to address are not limited to the aforementioned problems, and may be expanded in various ways without departing from the spirit and scope of the disclosure.

According to various example embodiments of the disclosure, in an electronic device including a housing (e.g., 400 in FIG. 5), the housing may include: an aluminum substrate (e.g., 410 in FIG. 5), a thermal spray coating layer (e.g, 420 in FIG. 5) formed on the aluminum substrate, and including a first area having a first thickness (e.g., t1 in FIG. 5), and a second area having a second thickness (e.g., t2 in FIG. 5) less than the first thickness, an oxide film layer (e.g., 430 in FIG. 5) formed on the thermal spray coating layer or the aluminum substrate, and a deposition film layer (e.g., 440 in FIG. 5) formed on at least a portion of the thermal spray coating layer.

According to an example embodiment, the deposition film layer may be formed on the first area of the thermal spray coating layer.

According to an example embodiment, the deposition film layer may be formed on at least a portion of the oxide film layer.

According to an example embodiment, a difference between the first thickness and the second thickness may be 1 μm or more and 5 μm or less.

According to an example embodiment, as a difference between the first thickness and the second thickness increases, a brightness difference between the first area and the second area may increase.

According to an example embodiment, the oxide film layer may have a thickness of 7 μm or more and 10 μm or less.

According to an example embodiment, the deposition film layer may have a thickness of 2 μm or less.

According to an example embodiment, the electronic device may include a front surface on which a display is disposed, a rear surface opposite to the front surface, and a side surface disposed between the front surface and the rear surface. The housing may include the rear surface and the side surface of the electronic device.

According to an example embodiment, the electronic device may further include a battery mounted inside the housing.

According to an example embodiment, the electronic device may further include a display.

According to an example embodiment, the housing may have a gloss similar to that of a high-gloss metallic material.

According to various example embodiments of the disclosure, a method of manufacturing a housing for an electronic device may include: forming a thermal spray coating layer on an aluminum substrate through thermal spray coating, polishing the thermal spray coating layer, machining at least a portion of the thermal spray coating layer with a laser such that the thermal spray coating layer includes a first area having a first thickness and a second area having a second thickness less than the first thickness, forming an oxide film layer through an anodizing process, forming a deposition film layer through a deposition process, and machining at least a portion of the deposition film layer with a laser.

According to an example embodiment, the deposition film layer may be formed on the first area of the thermal spray coating layer.

According to an example embodiment, a difference between the first thickness and the second thickness may be 1 μm or more and 5 μm or less.

According to an example embodiment, as a difference between the first thickness and the second thickness increase, a brightness difference between the first area and the second area may increase.

According to an example embodiment, the oxide film layer may have a thickness of 7 μm or more and 10 μm or less.

According to an example embodiment, the deposition film layer may have a thickness of 2 μm or less.

According to an example embodiment, the electronic device may include: a front surface on which a display is disposed, a rear surface opposite to the front surface, and a side surface disposed between the front surface and the rear surface. The housing may include the rear surface and the side surface of the electronic device.

According to an example embodiment, the electronic device may further include a display.

While the disclosure has been illustrated and described with reference to various example embodiments, it will be understood that the various example embodiments are intended to be illustrative, not limiting. It will be further understood by those skilled in the art that various changes in form and detail may be made without departing from the true spirit and full scope of the disclosure, including the appended claims and their equivalents. It will also be understood that any of the embodiment(s) described herein may be used in conjunction with any other embodiment(s) described herein.

What is claimed is:

1. An electronic device comprising a housing configured to be visible from an exterior of the electronic device, wherein the housing comprises:
an aluminum substrate;
a thermal spray coating layer formed on the aluminum substrate, and including a first area having a first thickness, and a second area having a second thickness less than the first thickness;
an oxide film layer formed on the thermal spray coating layer or the aluminum substrate; and
a deposition film layer formed on at least a portion of the thermal spray coating layer.

2. The electronic device of claim 1, wherein the deposition film layer is formed on the first area of the thermal spray coating layer.

3. The electronic device of claim 1, wherein the deposition film layer is formed on at least a portion of the oxide film layer.

4. The electronic device of claim 1, wherein a difference between the first thickness and the second thickness is 1 μm or more and 5 μm or less.

5. The electronic device of claim 1, wherein as a difference between the first thickness and the second thickness increases, a brightness difference between the first area and the second area increases.

6. The electronic device of claim 1, wherein the oxide film layer has a thickness of 7 μm or more and 10 μm or less.

7. The electronic device of claim 1, wherein the deposition film layer has a thickness of 2 μm or less.

8. The electronic device of claim 1, further comprising:
a front surface on which a display is disposed; a rear surface opposite to the front surface; and a side surface disposed between the front surface and the rear surface,
wherein the housing includes the rear surface and the side surface of the electronic device.

9. The electronic device of claim 1, further comprising:
a battery mounted inside the housing.

10. The electronic device of claim 1, further comprising:
a display.

11. The electronic device of claim 1, wherein the housing has a gloss substantially the same as a high-gloss metallic material.

12. The electronic device of claim 1, wherein the thermal spray coating layer comprises a coating material having a specific gravity higher than a specific gravity of the aluminum substrate.

13. The electronic device of claim 1, wherein the thermal spray coating layer comprises a coating material having a rigidity higher than a rigidity of the aluminum substrate.

14. A method of manufacturing a housing for an electronic device, the method comprising:
forming a thermal spray coating layer on an aluminum substrate through thermal spray coating;
polishing the thermal spray coating layer;
machining at least a portion of the thermal spray coating layer with a laser such that the thermal spray coating layer comprises a first area having a first thickness and a second area having a second thickness less than the first thickness;
forming an oxide film layer through an anodizing process;
forming a deposition film layer through a deposition process; and
machining at least a portion of the deposition film layer with a laser.

15. The method of claim 14, wherein the deposition film layer is formed on the first area of the thermal spray coating layer.

16. The method of claim 14, wherein the deposition film layer is formed on at least a portion of the oxide film layer.

17. The method of claim 14, wherein a difference between the first thickness and the second thickness is 1 μm or more and 5 μm or less.

18. The method of claim 14, wherein the housing has a gloss substantially the same as a high-gloss metallic material.

19. The method of claim 14, wherein the thermal spray coating layer comprises a coating material having a specific gravity higher than a specific gravity of the aluminum substrate.

20. The method of claim 14, wherein the thermal spray coating layer comprises a coating material having a rigidity higher than a rigidity of the aluminum substrate.
